(19) United States
(12) Patent Application Publication
(10) Pub. No.: US 2008/0315310 A1
(43) Pub. Date: Dec. 25, 2008

(54) HIGH K DIELECTRIC MATERIALS INTEGRATED INTO MULTI-GATE TRANSISTOR STRUCTURES

(76) Inventors: Willy Rachmady, Beaverton, OR (US); Jack Kavalieros, Portland, OR (US); Uday Shah, Portland, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/765,023

(22) Filed: Jun. 19, 2007

(51) Int. Cl. H01L 27/12; H01L 21/84

(52) U.S. Cl. 257/347; 438/157; 257/E27.112; 257/E21.7

(57) ABSTRACT

Embodiments of the present invention relate to the fabrication of three-dimensional multi-gate transistor devices with high aspect ratio semiconductor bodies through the use of a high K dielectric material layer which is selectively wet etched to from a high K gate dielectric. In one specific embodiment, the high K gate dielectric comprises hafnium oxide, the etch stop layer comprises silicon oxide, and the etchant comprise phosphoric acid conditioned with silicon nitride.

### BACKGROUND OF THE INVENTION

1. Field of Invention

The field of invention relates generally to the field of microelectronic integrated circuit manufacturing and, more specifically but not exclusively, relates to CMOS (complementary metal oxide semiconductor) devices having a three-dimensional multi-gate semiconductor body.

2. State of the Art

In a conventional metal oxide semiconductor field effect transistor (MOSFET), the source, channel, and drain structures are constructed adjacent to each other within the same plane. The gate dielectric is formed on the channel area and the gate electrode is deposited on the gate dielectric. The transistor is controlled by applying a voltage to the gate electrode thereby allowing a current to flow through the channel between the source and drain.

An alternative to methods of building planar MOSFETs has been proposed to help alleviate some of the physical barriers to scaling down existing designs. One such alternative method involves the construction of three dimensional MOSFETs, in the form of a multi-gate transistor such as a dual-gate field effect transistor (FinFET) or a tri-gate transistor, as a replacement for the conventional planar MOSFETs.

Three-dimensional transistor designs, such as the dual-gate FinFET and the tri-gate transistor, allow tighter packing of the same number of transistors on a semiconductor device by using vertical or angled surfaces for the gates. A tri-gate device comprises three gates situated on three surfaces of a semiconductor body (also referred to as a “fin”), generally a top gate and two opposing side gates.

As these transistor devices are scaled down to enable the integration of more transistors on a single semiconductor device, the dimensions of the material layers used in their formation must be reduced in order to help make the devices thinner and smaller. One such material layer is the gate dielectric layer. Typically, the gate dielectric layer is made out of silicon oxide. However, when the silicon oxide layer is scaled down, it does not have sufficient permittivity (or high enough dielectric constant), which causes charge leakage or gate leakage through direct tunneling, which leads to unreliable and/or defective devices. Thus, high K dielectrics (i.e, dielectric materials with a dielectric constant higher than that of silicon dioxide), such as tantalum pentaoxide (Ta₂O₅), titantium oxide (TiO₂), and hafnium oxide (HfO₂), can be used to replace silicon dioxide.

As will be understood to those skilled in the art, the high K dielectric material is deposited over the semiconductor body prior to the formation of the gate electrode and the portions of the high K dielectric not between the gate electrode and the semiconductor body are removed. One drawback in the use of high K dielectric material is that they are generally difficult to remove by standard etching practices without damaging the semiconductor body. Thus, typical removal techniques involve high energy angled implantation from an ion beam apparatus. However, this technique also has issues including incomplete removal of the high K dielectric material from the semiconductor body sidewalls which can lead to lateral oxidation since the hermetic seal formed with the subsequent spacer formation (such as a nitride spacer) does not adequately seal the exposed high K dielectric material. Additionally, high energy implantation can result in gate corner damage and/or material loss from the semiconductor body. Moreover, angled implantation can limit the aspect ratio and pitch scaling of the semiconductor body, because high aspect ratios make it more difficult to direct the ion beam toward the sidewalls of the semiconductor body, as will be understood to those skilled in the art.

Therefore, it would be advantageous to develop techniques to selectively remove high K dielectrics during the fabrication of multi-gate transistors by eliminating the need to use high energy implantation, which, of course, eliminates the problems associated therewith and allows for the scaling of the multi-gate transistors.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 is an oblique view of an insulating substrate, according to the present invention;

FIG. 2 is an oblique view of the insulating substrate of FIG. 1 after a semiconductor body has been formed thereon, according to the present invention;

FIGS. 3 and 4 illustrate an oblique view and a side cross-sectional view, respectively, of the structure of FIG. 2, wherein an etch layer has been deposited on the semiconductor body, according to the present invention;

FIGS. 5 and 6 illustrate an oblique view and a side cross-sectional view, respectively, of the structure of FIGS. 3 and 4 after patterning a high K dielectric material layer adjacent the semiconductor body, according to the present invention;

FIGS. 7 and 8 illustrate an oblique view and a side cross-sectional view, respectively, of the structure of FIGS. 5 and 6 after the formation of a gate electrode, according to the present invention; and

FIGS. 9 and 10 illustrate an oblique view and a side cross-sectional view, respectively, of the structure of FIGS. 7 and 8, after the wet etching of the high K dielectric material layer to form a high K gate dielectric, according to the present invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Embodiments of the present invention relate to the fabrication of three-dimensional multi-gate transistor devices with high aspect ratio semiconductor bodies (i.e., aspect ratio greater than 1) through the use of a high K dielectric material layer which is selectively wet etched to from a high K gate. The present invention will be described in terms of a tri-gate transistor; however, one skilled in the relevant art will recognize that the invention can be practiced with other transistor structures, such as dual-gate field effect transistors, or without one or more of the specific details, or with other methods, components, materials, etc. In other instances, well-known structures, materials, or operations are not shown or described in detail to avoid obscuring aspects of the invention.

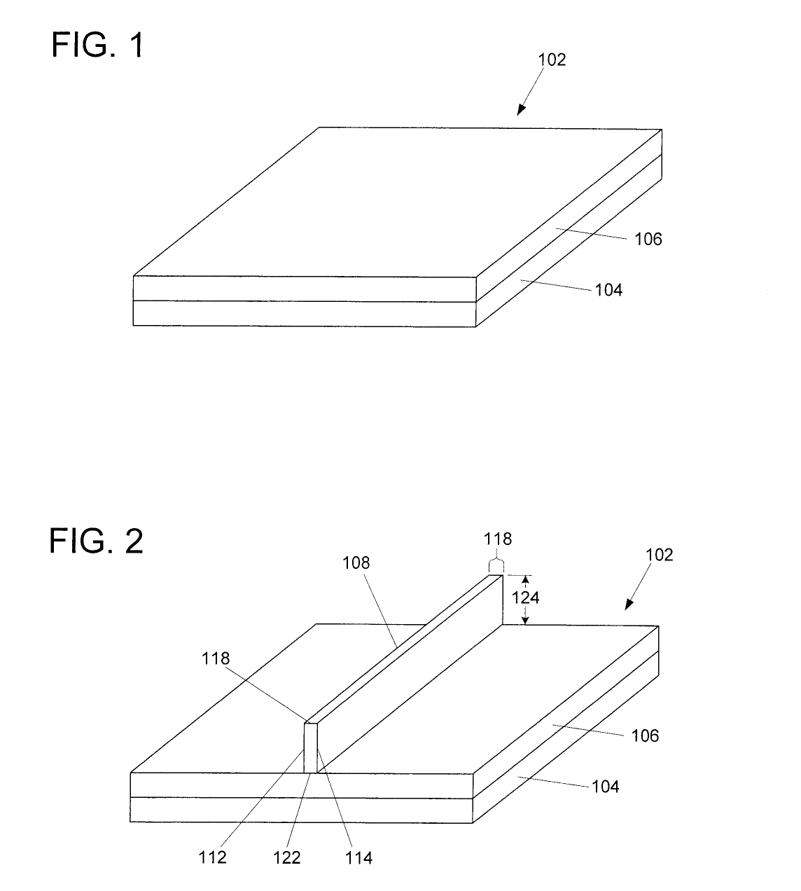

A method of fabricating a tri-gate transistor in accordance with an embodiment of the present invention is illustrated in FIGS. 1-10. As shown in FIG. 1, the tri-gate transistor may be formed on an insulating substrate 102. The insulating substrate 102 may include a supporting substrate 104, such as a monocrystalline silicon substrate or a gallium arsenide substrate, upon which is formed in insulating layer 106, such as a silicon dioxide film. The tri-gate transistor, however, can be formed on any well-known insulating substrate such as substrates formed from nitrides, oxides, and sapphires.

As shown in FIG. 2, a semiconductor body 108 may be formed on the insulating layer 106 of the insulating substrate 102 and extending substantially perpendicularly therefrom. The semiconductor body 108 can be formed of any well-known semiconductor material, including, but not limited to, silicon (Si), germanium (Ge), silicon germanium (SiₓGe_{y}), gallium arsenide (GaAs), indium antimonide (InSb), gallium phosphide (GaP), gallium antimonide (GaSb) and carbon nanotubes, which can be reversibly altered from a dielectric state to a conductive state by applying external electrical controls, as will understood to those skilled in the art. In one example, the semiconductor body 108 may be a single crystalline film when the transistor is used in high performance applications, such as in a high density circuit (e.g., a microprocessor). The semiconductor body 108, however, can be a polycrystalline film when the transistor is used in applications requiring less stringent performance, such as in liquid crystal displays. The insulating layer 106 insulates the semiconductor body 108 from the supporting substrate 104. The semiconductor body 108 has a pair of laterally opposite sidewalls, a first sidewall 112 and a second sidewall 114 separated by a distance which defines a semiconductor body width 118. Additionally, the semiconductor body 108 has a top surface 116 opposite a bottom surface 122 formed on the insulating substrate 102. The distance between the semiconductor body top surface 116 and the semiconductor body bottom surface 122 defines a semiconductor body height 124.

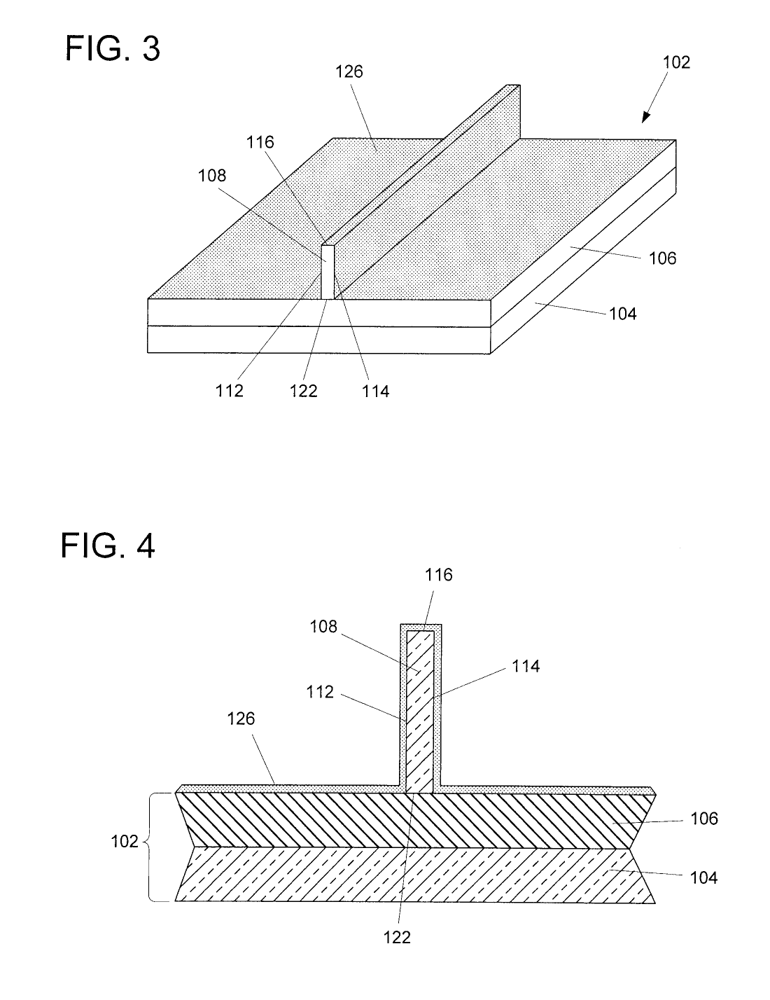

As shown in FIGS. 3 and 4 according to the present invention, a thin etch stop layer 126 is deposited over the semiconductor body 108, i.e., formed on or adjacent to the first sidewall 112, the top surface 116, and on or adjacent to second sidewall 114 of the semiconductor body 108. In one embodiment, the thin etch stop layer 126 between about one to five monolayers thick. In a specific embodiment, the thin etch stop layer 126 is silicon dioxide. It is, of course, understood that the thin etch stop layer 126 may be formed from any material that is selective to the etching of a gate dielectric material that will be subsequently deposited. The thin etch stop layer 126 can be formed by any appropriate technique known in the art, including, but not limited to atomic layer deposition.

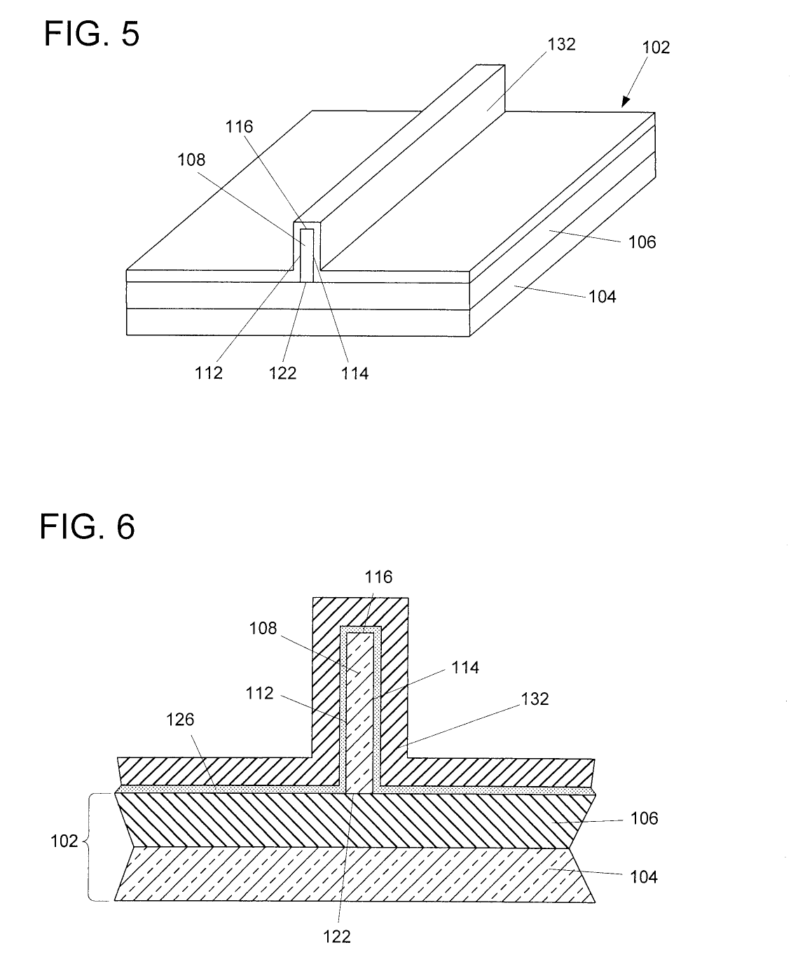

As shown in FIGS. 5 and 6, a high K dielectric material layer 132 is formed on the thin etch stop layer 126. The high K dielectric material layer 132 can be any appropriate high K dielectric material, such as a metal oxide dielectric, including but not limited to tantalum pentaoxide (Ta₂O₅), titanium oxide (TiO₂), and hafnium oxide (HfO₂). The high K dielectric material layer 132 can be formed and patterned by any appropriate deposition technique known in the art. Although the high K dielectric material layer 132 is shown to be patterned to reside proximate the semiconductor body 108, it could extend proximate the insulation substrate 102.

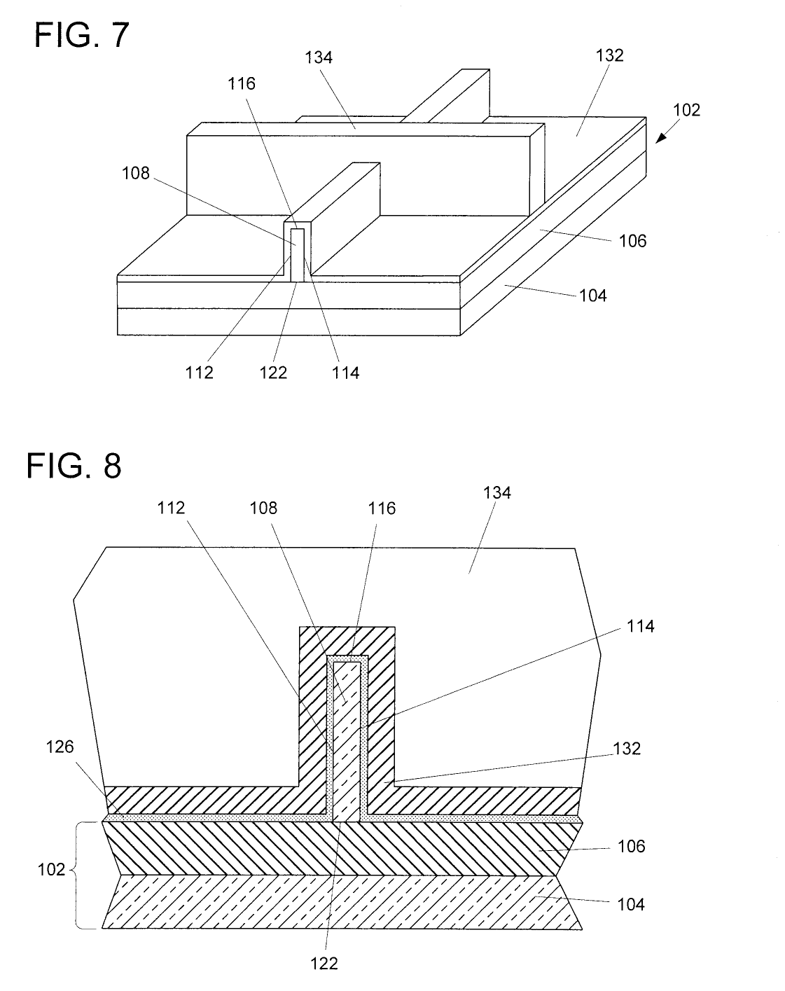

As shown in FIGS. 7 and 8, a gate electrode 134 is formed on or adjacent high K dielectric material layer 132 which is on or adjacent the top surface 116 of semiconductor body 108 and on or adjacent the high K dielectric material layer 132 which is on or adjacent the first sidewall 112 and the second sidewall 114 of the semiconductor body 108. The gate electrode 134 has a pair of laterally opposite sidewalls 136 and 138 separated by a distance which defines the gate length (Lg) 142 of the transistor. In an embodiment of the present invention, the laterally opposite sidewalls 136 and 138 of the gate electrode 134 run in a direction substantially perpendicular to the laterally opposite first sidewall 112 and second sidewall 114 of semiconductor body 108.

The gate electrode 134 can be patterned by any appropriate technique known in the art, such as lithography, and can be formed of any suitable gate electrode material, including but not limited polycrystalline silicon and metals. The metal material may include, but are not limited to tungsten, tantalum, titanium, and their nitrides. As will be understood to those skilled in the art, the gate electrode 134 need not necessarily be a single material and can be a composite stack of thin films, including but not limited to a polycrystalline silicon/metal electrode.

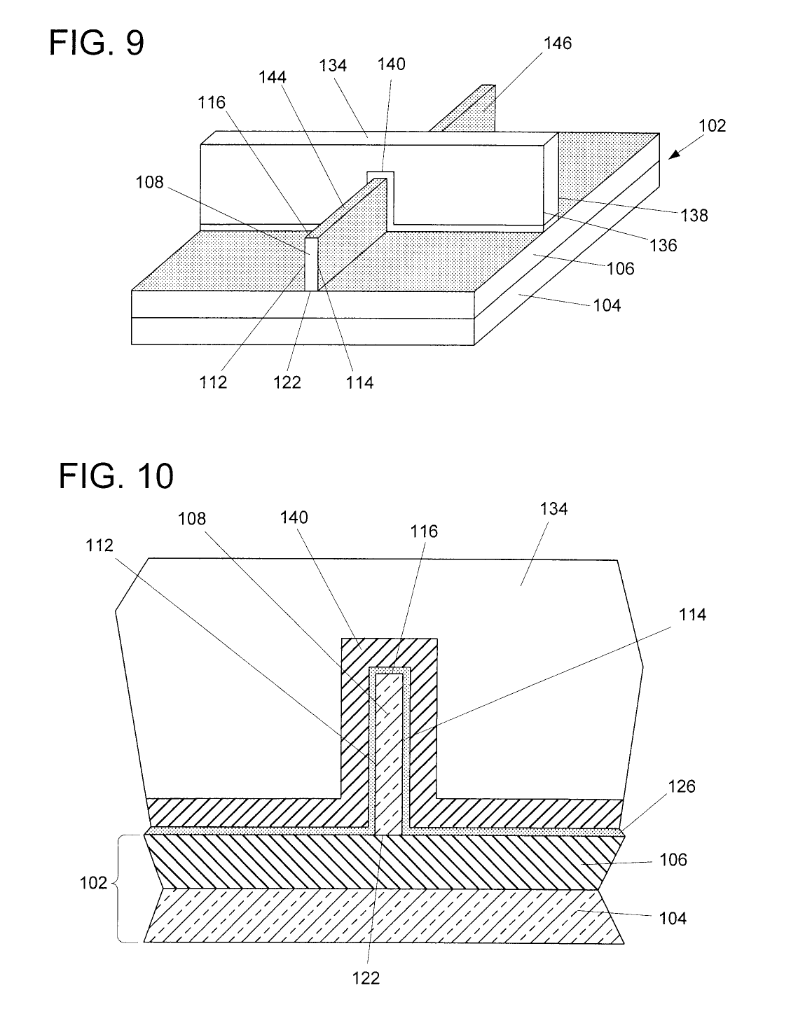

As shown in FIGS. 9 and 10, a portion the high K dielectric material layer 132 which is not covered by the gate electrode 134 is selectively removed to form a high K gate dielectric 140. In the present invention, the portion of the high K dielectric material layer 132 is removed with a wet etch, rather than high energy implantation. In one embodiment, the high K dielectric material layer 132 is hafnium oxide and the thin etch stop layer 126 is silicon dioxide. The etchant used for the hafnium oxide removal is phosphoric acid, which has been conditioned with silicon nitride (Si₃N₄) to etch the hafnium oxide, but have a zero or near zero etch rate for silicon dioxide.

The silicon nitride conditioned phosphoric acid etchant may prepared by stripping blanket silicon nitride film grown on silicon wafers in a phosphoric acid bath until its silicon dioxide etch rate is essentially reduced to zero. It has been found that after reaching a super-saturated state is a virtually perfect selectivity to silicon oxide is achieved. Experimental results are presented in the following table:

| Phosphoric | No. of silicon nitride | |
|---|---|---|
| Acid | blanketed wafers used to | Silicon dioxide etch rate |
| Condition | condition the solution | in angstroms per minute |
| Fresh | 0 | 0/50 |
| | 25 | 0.30 |
| | 50 | 0.15 |
| | 75 | 0.05 |
| Super-Saturated | 100 | −0.115 |

It has been found that for an silicon nitride conditioned phosphoric acid etchant with a concentration of between 70 and 95 weight percent, a silicon nitride concentration should be between about 0.001 and 0.002 weight percent to obtain the necessary selectivity. Additionally, a super-saturated state for the silicon nitride conditioned phosphoric acid etchant is herein defined as having a weight percentage of silicon nitride of greater than 0.002 percent.

The etching method of the present invention allows aggressive scaling of the aspect ratio and pitch of the semiconductor body 108 to obtain high performance tri-gate transistors with a high packing density. It will also be understood to those skilled in the relevant art, the present invention also results in a lower source/drain contact resistance by opening the semiconductor body sidewall for wrap-around contact formation. Furthermore, the etching method of the present invention substantially reduces or virtually eliminates the risk semiconductor body loss (which can occur in high energy implantation), as the material etch stops precisely on the thin etch stop layer 126.

Although the etchant of the present invention is described as phosphoric acid conditioned with silicon nitride, it is, of course, understood that various acids and conditioners could be used depending on the high K dielectric layer material and the thin etch stop material.

Referring to FIG. 9, the semiconductor body 108 has a source region 144 and a drain region 146 on opposite sides of gate electrode 134. The source region 144 and the drain region 146 are formed of the same conductivity type such as N-type or P-type conductivity. The source region 144 and the drain region 146 can be formed of uniform concentration or can include sub-regions of different concentrations or doping profiles such as tip regions (e.g., source/drain extensions). In an embodiment of the present invention, when a transistor is a symmetrical transistor, the source region 144 and the drain region 146 will have the same doping concentration and profile. In an embodiment of the present invention, when a transistor is formed as an asymmetric transistor, the doping concentration and profile of the source region 144 and the drain region 146 may vary in order to obtain a particular electrical characteristic.

The portion of semiconductor body 108 located between the source region 144 and the drain region 146, defines a channel region (not shown). The channel region can also be defined as the area of the semiconductor body 108 surrounded by the gate electrode 134. At times however, the source/drain region may extend slightly beneath the gate electrode through, for example, diffusion to define a channel region slightly smaller than the gate electrode length (Lg).

By providing a high K gate dielectric 140 and a gate electrode 134 which surrounds the semiconductor body 108 on three sides, the tri-gate transistor is characterized in having three channels and three gates, one gate which extends between the source and drain regions on first sidewall 112 of silicon body 108, a second gate which extends between the source and drain regions on the top surface 116 of silicon body 108, and the third gate which extends between the source and drain regions on the second sidewall 114 of silicon body 108. The gate “width” (Gw) of transistor is the sum of the widths of the three channel regions. That is, the gate width of transistor is equal to the height 124 of semiconductor body 108 at the first sidewall 112, plus the width 118 of semiconductor body of 108 at the top surface 116, plus the height 124 of semiconductor body 108 at the second sidewall 114. Because the channel region is surrounded on three sides by gate electrode 134 and high K gate dielectric 140, the transistor can be operated in a fully depleted manner wherein when transistor is turned “on” the channel region fully depletes thereby providing the advantageous electrical characteristics and performance of a fully depleted transistor.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method for fabricating a multi-gate transistor comprising:
providing an insulating substrate;
forming a semiconductor body on said insulating substrate, said semiconductor body having a first sidewall and a laterally opposing second sidewall;
depositing a thin etch stop layer on said semiconductor body;
depositing a high K dielectric material layer abutting at least a portion of said thin etch stop layer adjacent said first sidewall and said second sidewall of said semiconductor body;
forming a gate electrode adjacent said high K dielectric material layer; and
removing a portion of said high K dielectric material layer which not between said gate electrode and said semiconductor body with a wet etch process stopping on said thin etch stop layer.

2. The method of claim 1, wherein depositing said thin etch stop layer comprises depositing a thin silicon dioxide layer.

3. The method of claim 2, wherein depositing said thin silicon dioxide layer comprises a depositing between about one and five monolayers of silicon dioxide.

4. The method of claim 1, wherein depositing said high K dielectric material layer comprises depositing a hafnium oxide layer.

5. The method of claim 1, wherein removing said portion of said high K dielectric material layer comprises wet etching said portion of said high K dielectric material layer with a solution comprising phosphoric acid.

6. The method of claim 5, wherein said wet etching said portion of said high K dielectric material layer with said phosphoric acid solution comprises wet etching said portion of said high K dielectric material layer with a phosphoric acid solution super-saturated with silicon nitride.

7. The method of claim 5, wherein said wet etching said portion of said high K dielectric material layer with a phosphoric acid solution comprises wet etching said portion of said high K dielectric material layer with a phosphoric acid solution comprising between about 70 and 95 weight percent of phosphoric acid and between about 0.001 and 0.002 weight percent of silicon nitride.

8. The method of claim 1, wherein said forming said semiconductor body comprises for said semiconductor body from the group of materials consisting of silicon (Si), germanium (Ge), silicon germanium (SiₓGe_{y}), gallium arsenide (GaAs), indium antimonide (InSb), gallium phosphide (GaP), gallium antimonide (GaSb) and carbon nanotubes.

9. A multi-gate transistor comprising:
an insulating substrate;
a semiconductor body on said insulating substrate, said semiconductor body having a first sidewall and a laterally opposite second sidewall;
a thin etch stop layer proximate said semiconductor body;
a gate electrode extending over said semiconductor body; and
a high K gate dielectric disposed between said semiconductor body first sidewall and said gate electrode, and between said semiconductor body second sidewall and said gate electrode.

10. The multi-gate transistor of claim 9, wherein said thin etch stop layer comprises silicon dioxide.

11. The multi-gate transistor of claim 10, wherein said silicon dioxide thin etch stop layer is between about 1 and 5 monolayers thick.

12. The multi-gate transistor of claim 10, wherein said high K gate dielectric comprises hafnium oxide.

13. A multi-gate transistor formed by the method comprising:
providing an insulating substrate;
forming a semiconductor body on said insulating substrate, said semiconductor body having a first sidewall and a laterally opposing second sidewall;
depositing a thin etch stop layer on said semiconductor body;
depositing a high K dielectric material layer abutting at least a portion of said thin etch stop layer adjacent said first sidewall and said second sidewall of said semiconductor body;
forming a gate electrode adjacent said high K dielectric material layer; and
removing a portion of said high K dielectric material layer which not between said gate electrode and said semiconductor body with a wet etch process stopping on said thin etch stop layer.

14. The multi-gate transistor of claim 13, wherein depositing said thin etch stop layer comprises depositing a thin silicon dioxide layer.

15. The multi-gate transistor of claim 14, wherein depositing said thin silicon dioxide layer comprises a depositing between one and five monolayers of silicon dioxide.

16. The multi-gate transistor of claim 13, wherein depositing said high K dielectric material layer comprises depositing a hafnium oxide layer.

17. The multi-gate transistor of claim 13, wherein removing said portion of said high K dielectric material layer comprises wet etching said portion of said high K dielectric material layer with a solution comprising phosphoric acid.

18. The multi-gate transistor of claim 17, wherein said wet etching said portion of said high K dielectric material layer with said phosphoric acid solution comprises wet etching said portion of said high K dielectric material layer with a phosphoric acid solution super-saturated with silicon nitride.

19. The multi-gate transistor of claim 17, wherein said wet etching said portion of said high K dielectric material layer with a phosphoric acid solution comprises wet etching said portion of said high K dielectric material layer with a phosphoric acid solution comprising between about 70 and 95 weight percent of phosphoric acid and between about 0.001 and 0.002 weight percent of silicon nitride.

20. The multi-gate transistor of claim 13, wherein said forming said semiconductor body comprises for said semiconductor body from the group of materials consisting of silicon (Si), germanium (Ge), silicon germanium (SiₓGe_{y}), gallium arsenide (GaAs), indium antimonide (InSb), gallium phosphide (GaP), gallium antimonide (GaSb) and carbon nanotubes.
